(19) United States
(12) Patent Application Publication
(10) Pub. No.: US 2008/0143559 A1
(43) Pub. Date: Jun. 19, 2008

(54) Appliance Control Panel

(76) Inventors: Paul H. Dietz, Hopkinton, MA (US); Jonathan Westhues, Cambridge, MA (US); Darren L. Leigh, Somerville, MA (US)

Correspondence Address: MITSUBISHI ELECTRIC RESEARCH LABORATORIES, INC., 201 BROADWAY, 8TH FLOOR, CAMBRIDGE, MA, 02139, US

(21) Appl. No.: 11/611,919

(22) Filed: Dec. 18, 2006

(51) Int. Cl. H03K 17/94

(52) U.S. Cl. 341/20; 341/33

(57) ABSTRACT

An appliance control panel detects on ON gesture by a user approximately near a set of electrodes in a surface of the appliance, in which the electrodes sense a capacitive coupling to the user. The appliance is turned on in ON in response to the detecting of the ON gesture by the user. A capacitive coupling substantially near a particular one of the set of electrodes by the user is detected to perform a control action.

### FIELD OF THE INVENTION

This invention relates generally to control panels, and more particularly to touch sensitive control panels for consumer appliances.

### BACKGROUND OF THE INVENTION

Consumer appliances often include a number of controls. For example, stoves typically have at least one control for each heating element. In the prior art, relatively large mechanical dials and large push buttons are the most common controls. These are difficult to clean and aesthetically unappealing to many users. With the emergence of microprocessor controlled appliances, electro-mechanical controls have been replaced by electronically operated controls. Membrane switches and capacitive touch switches allow manufacturers to produce flat control panels that are easy to clean, and have a more appealing design.

Unfortunately, as appliance sophistication has increased, so have the number of controls. Many appliances have a large number of controls. Many users find these dense control panels unattractive. This has lead to a desire to ‘hide’ the control panel so that the appliance can have a smooth appearance. For example, some dishwashers have their controls on the top side of the door.

U.S. Pat. No. 5,239,152 describes a capacitive touch sensitive control panel, which only appears when back lighting is active. The back lighting includes light sources which are individually and selectively actuatable by conductive sensor pads. When a particular light source is not actuated, the overlaying graphic symbol is hidden. When the source is actuated, the overlaying graphic symbol is visible. Thus, in a “sleep” mode, all of the back light sources are deactuated, and in a “use” mode one or more of the back light sources are actuated. The problem with that panel is that the appliance must be “on” in order to enable activation of any of the controls. Also, activation can be caused by an accidental touching of one of the pads.

Capacitive touch controls used in appliances are generally placed behind plastic, glass or ceramic panels. Typically, audio feedback is used to indicate a switch actuation. Because there is no tactile feedback of a successful touching, this audio cue is quite important. On many appliances it is easy to accidentally actuate a capacitive touch switch when cleaning or simply leaning on the control panel. Capacitive coupling on a touch sensor is a function of both finger size and distance to the sensor. It is difficult to set a threshold so that a small, gloved finger will actuate a control, but a large thumb nearby, not actually touching, will not.

Clearly, there is a need for an apparatus and method which enables aesthetically pleasing control panels, which can appear and disappear appropriately, and can reduce accidental actuation.

### SUMMARY OF THE INVENTION

The embodiment of the present invention provide a control panel, which can appear and disappear as needed via programmatic or user interaction. The panel uses capacitive sensing to determine both an area of a touch, and to search for user control gestures. In the preferred embodiment, a touch event is determined by a change in physical pressure on the control panel, and capacitive coupling information is used to determine which, if any control this event is associated with. The system can provide both audio and tactile feedback of the actuation event.

### BRIEF DESCRIPTION OF THE DRAWINGS

FIG. 1A is a side view of an appliance control panel according to an embodiment of the invention;

FIG. 1B is a top view of the appliance control panel of FIG. 1A and a controller;

FIG. 2 is a side view of a tactile response unit of the control panel of FIG. 1A;

FIG. 3 is a side view of an alternative embodiment of the tactile response unit of FIG. 2; and

FIG. 4 is a flow diagram of a method for operating the appliance control panel of FIG. 1A.

### DETAILED DESCRIPTION OF THE PREFERRED EMBODIMENTS

Control Panel

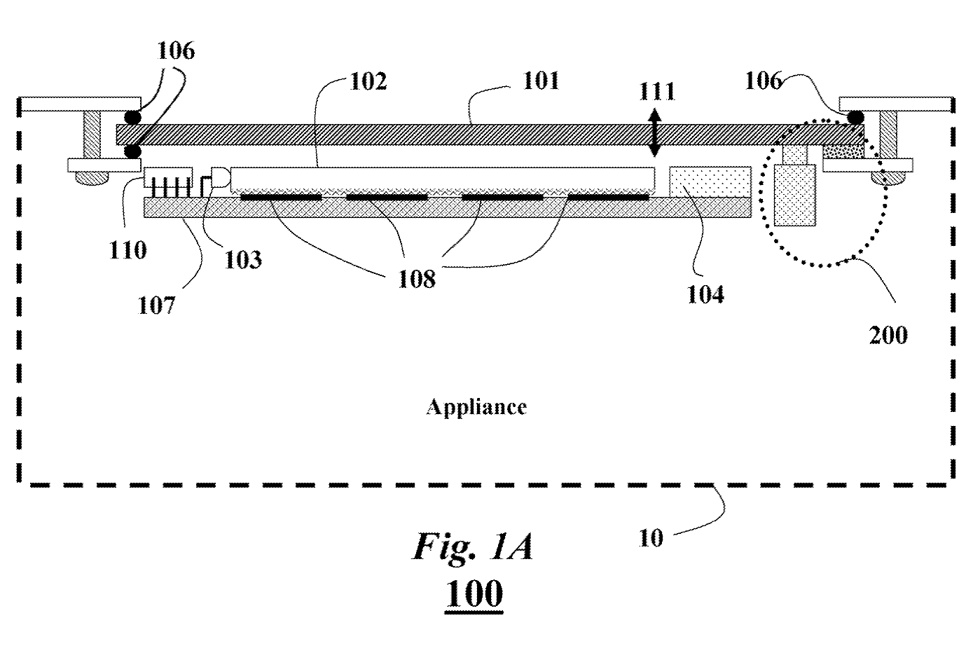

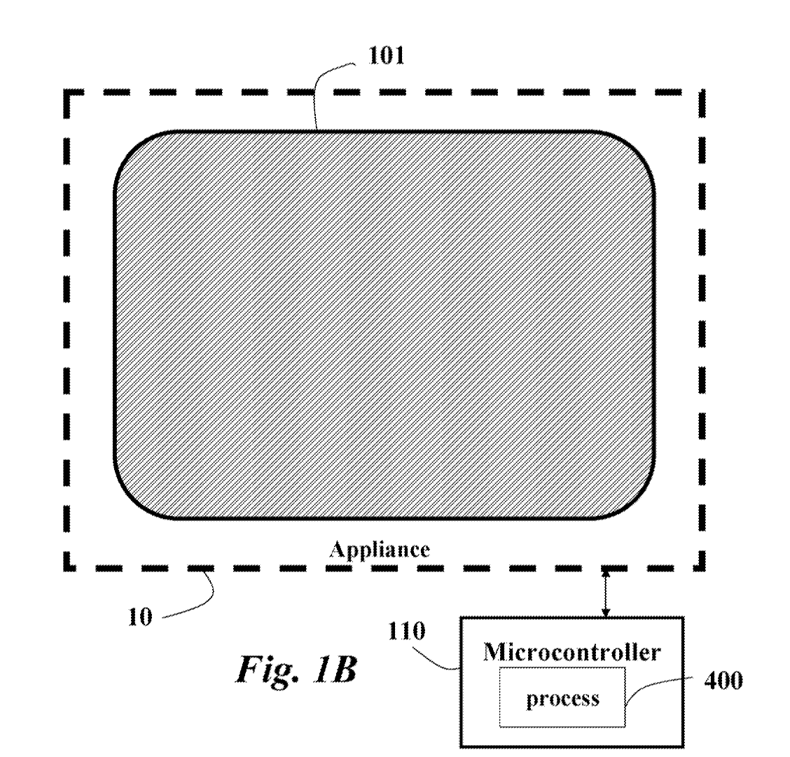

FIGS. 1A and 1B show a control panel 100 for an appliance 10 according to an embodiment of the invention. As used herein, an appliance 10 can be a stove, microwave unit, dish washer, washing machine, dryer, air conditioning unit, rice cooker, coffee maker, entertainment device, security system, environmental control, or any other similar type of devices that require interaction with a user in order to operate.

The control panel includes a bezel 101 and light source 103. A light guide 102 is arranged between the bezel and light source 103. The light source can include individually controllable light elements. The panel also includes display elements 104, such as LED displays.

The bezel 101 is in contact with a tactile response unit 200. The bezel also is supported by compressible separators 106.

A printed circuit board 107 includes a set of electrodes 108. The electrodes can sense a capacitive coupling to ground, via, e.g., a user. The set of electrodes are aligned with the display elements. A subset of the electrodes 108 can be associated with specific control actions when a touch even occurs in proximity to a single electrode. For example, a control action can be to adjust the temperature of a heating element. Another control action can be setting a timer. Capacitive coupling to multiple electrodes in particular sequences can be used to turn the appliance ON and OFF. When the appliance is OFF, any of the control actions cannot be performed at all. Only when the appliance is ON, an the control actions be performed.

When the appliance is OFF, relatively small changes in electrode capacitance can be used to detect user interactions at significantly greater distances than a touch event. Thus, when the appliance is OFF, a wave-like hand gesture near the bezel can be used to turn the appliance ON. The hand does not need to be in close proximity to electrodes or actually touch the electrodes. For example, the gesture can be a couple of centimeters above the bezel. Furthermore, the hand does not need to be bare, but can be inserted in a glove or oven mitt. When the appliance is ON relatively large changes in electrode capacitance can indicate close proximity to a particular electrode during a touch event.

The electronics of the control panel are connected to a microcontroller 110. The microcontroller executes a method process 400 for operating the control panel.

The bezel is substantially planar. The bezel 101 can be made of a material such as plastic, glass or ceramic, which allows some light to pass through, and can also serve as a dielectric in conjunction with the electrodes 108. When viewed without backlighting, the control panel is not visible, giving the impression of an uncluttered surface.

The bezel serves several purposes. Touching the bezel, in a predetermined manner using a wave-like gesture activated selected electronics. For example, the light source 103, displays elements 104 and the tactile response unit 200 are turned on. The capacitive sensing electrodes 108 can remain on at all times.

The light guide 102 is constructed to allow capacitive sensing by the electrodes 108. Plastic light guides and fiber optic weaves are examples of acceptable materials for the light guide.

Various graphics can be applied to either the rear of the bezel, or the front of the light guide that projects as images on the bezel when the light source 103 is activated. The images are used to guide the operation of the appliance by the user.

The tactile response unit 200 provides pressure sensing and haptic feedback response. The compressible separator 106 allows a limited amount of motion 111 for the bezel. Depending upon the size and position of the electrodes 108, additional electrodes can be added to recognize specific user gestures. The printed circuit board 107 can include some or all of the supporting circuitry, including the microcontroller 110.

Tactile Response Unit

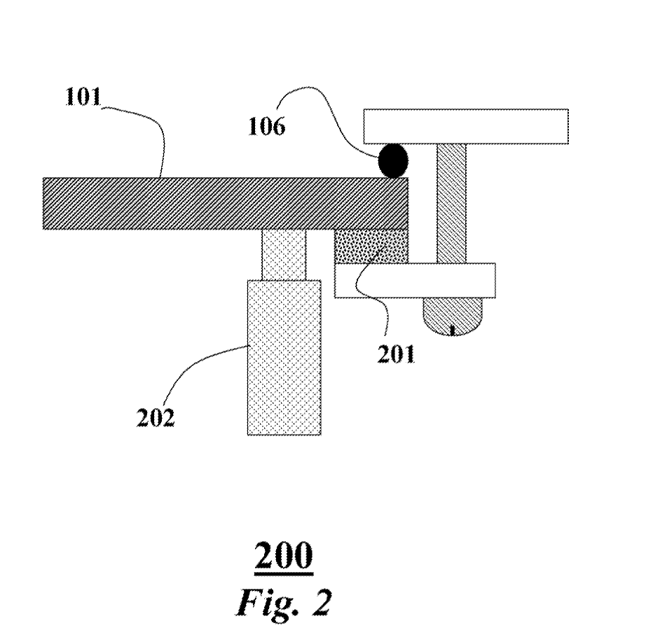

FIG. 2 shows components of the tactile response unit 200 in greater detail. The bezel 101 is disposed on a force sensor 201. Suitable force sensors include elastomeric force sensors, which change resistance dependent upon the applied force. An actuator 202 provides a mechanism to apply an impulsive force to the bezel. Suitable actuators include solenoids, and piezoelectric transducers.

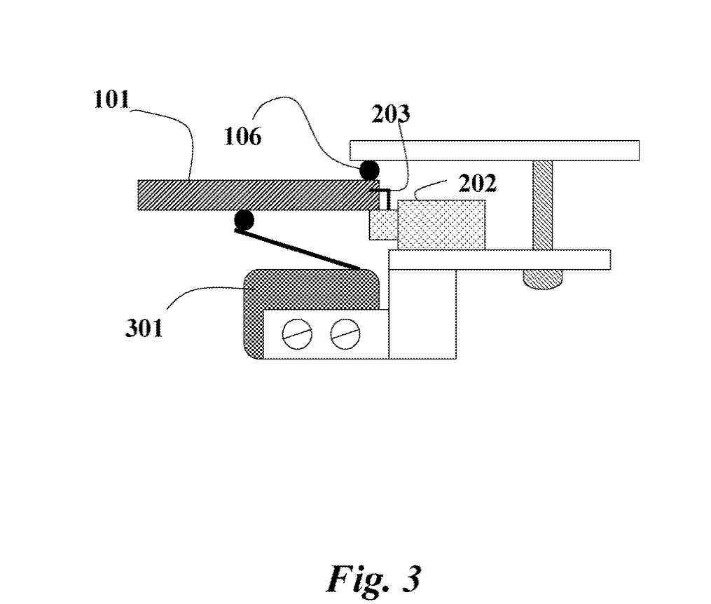

FIG. 3 shows an alternative embodiment of the tactile response unit 200. In this embodiment, the bezel 101 is disposed on a mechanical switch 301 for activation. Activation of individual controls is determined by the combination of proximity to an electrode 108, while providing sufficient force to activate the switch 301.

It is desirable to prevent the button clicking sensation when not activating a control. This can be accomplished with a mechanical locking mechanism 203 of the actuator.

The actuator solenoid 202 is energized only when capacitance measurements indicate that a finger is near a particular control. This provides an illusion of discrete buttons.

Method Operation

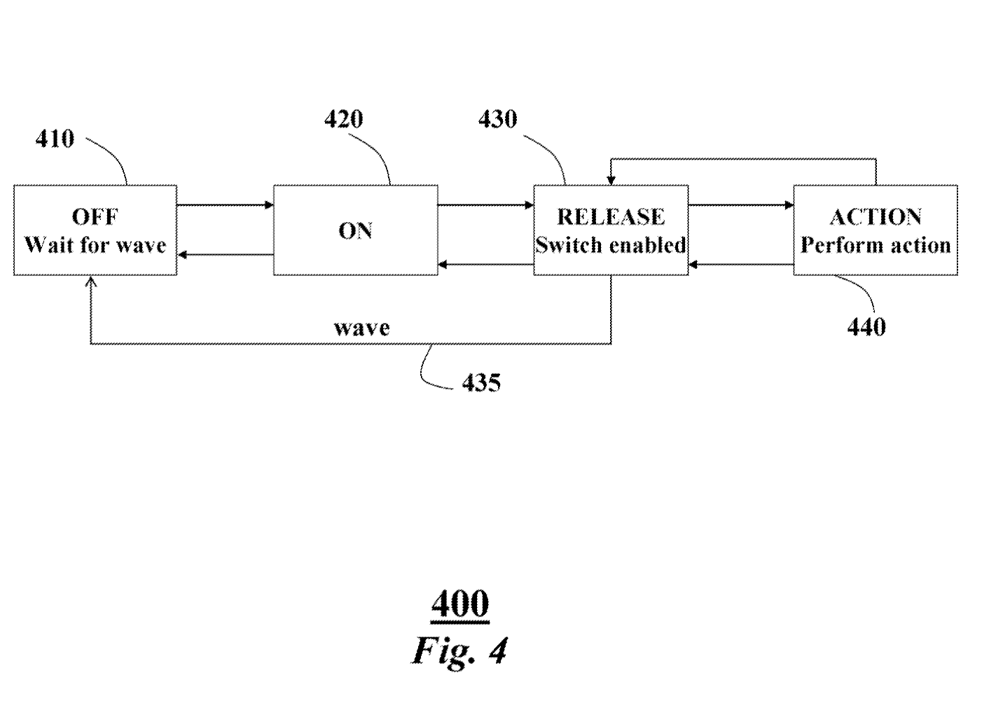

FIG. 4 shows the operation of process 400. Initially, the appliance is OFF. The term OFF is used here to indicate that a user cannot generally operate the appliance while the appliance is OFF. The only operation that is permitted is to turn the appliance ON. It is understood that in most modern electronically operated appliances the electronic circuits are in some standby state to be able to detect the ON command. For example, televisions and radios only response to ON commands from a remote controller while OFF.

While OFF, the appliance is waiting 410 to detect an ON gesture with a relatively high gain on the electrodes 108. One possible ON gesture is a wave of the hand near the electrodes 108, e.g., from left to right and left again. By using a gesture, accidental activation of a control by for example placing a hand on the bezel, can be eliminated. The ON gesture can be detected by sensing an order and timing in which some or all of the electrodes 108 are activated.

In response to the ON gesture, the lighting source 103 and display elements 104 can be activated 420 making them visible to the user. At this point, the appliance is ON, and the gain on the electrodes can be set relatively low. Now, the process is waiting to detect and perform a control action 440.

If no control action is detected within a predetermined amount of time, the process can time-out 435 and the appliance can be turned OFF in state 410. The appliance can also be turned OFF when a specific action completes, e.g., a washer has gone through all its cycles. Alternatively, the appliance can be turned OFF by an OFF gesture, e.g., a wave-like hand gesture in the opposite direction from the ON gesture.

A control action can also require two events. The sensing of the capacitive coupling and force is applied to the tactile response unit 200 by pressing on the bezel 101. In response to the pressure, the tactile response unit generates a haptic impulse to generate the feel of a ‘click’ by the bezel, and passes this event to the controller 110. For the alternative embodiment shown in FIG. 3, the sequence of events is altered. The lock 203 is released 430 only when there is sufficient capacitive coupling to only a single electrode, indicating that a use is about to press a button. Pressing on the bezel can then activate the switch 301 and perform the corresponding control action 440. If a user presses a location on the bezel which is not meant to be a control, there is no corresponding electrode, and the lock is not released. Thus, no click is perceived and no action is taken.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

We claim:

1. A method of operating an appliance, comprising the steps of:
detecting an ON gesture by a user approximately near a set of electrodes in a surface of an appliance, in which the electrodes sense a capacitive coupling to the user;
turning the appliance ON in response to the detecting of the ON gesture by the user; and
detecting the capacitive coupling substantially near a particular one of the set of electrodes by the user to perform a control action.

2. The method of claim 1, further comprising:
detecting an OFF gesture by the user near the set of electrodes; and
turning the appliance OFF in response to the detecting of the OFF gesture by the user.

3. The method of claim 1, further comprising:
activating a light source behind a bezel of the appliance when turning the appliance ON.

4. The method of claim 1, in which a gain on the set of electrodes is relatively high while the appliance is OFF, and the gain is relatively low while the appliance is ON.

5. The method of claim 3, in which the light source includes individually controllable light elements, each light element controllable by a particular one of the electrodes.

6. The method of claim 1, further comprising:
sensing a pressure on a bezel in the surface of the appliance while turning on the appliance ON.

7. The method of claim 6, further comprising:
providing a haptic impulse in response to the sensing the pressure.

8. The method of claim 1, further comprising:
locking the bezel in place while the appliance is OFF.

9. The method of claim 1, further comprising:
providing a haptic impulse in response to detecting the capacitive coupling substantially near the particular one of the set of electrodes.

10. The method of claim 1, further comprising:
turning the appliance OFF if the control action is not detecting in a predetermining amount of time.

11. An appliance control panel apparatus, comprising:
a set of electrodes in a surface of an appliance, in which the electrodes sense a capacitive coupling to a user;
means for detecting on ON gesture by the user approximately near the set of electrodes;
means for turning the appliance ON in response to the detecting of the ON gesture by the user; and
means detecting the capacitive coupling substantially near a particular one of the set of electrodes by the user to perform a control action.

12. The apparatus of claim 11, further comprising:
means for detecting an OFF gesture by the user near the set of electrodes; and
means for turning the appliance OFF in response to the detecting of the OFF gesture by the user.

13. The apparatus of claim 11, further comprising:
a light source behind a bezel of the appliance; and
means for activating the light source when turning the appliance ON.

14. The apparatus of claim 11, in which a gain on the set of electrodes is relatively high while the appliance if OFF, and the gain is relatively low while the appliance is ON.

15. The apparatus of claim 13, in which the light source includes individually controllable light elements, each light element controllable by a particular one of the electrodes.

16. The apparatus of claim 11, further comprising:
means for sensing a pressure on a bezel in the surface of the appliance while turning the appliance ON.

17. The apparatus of claim 16, further comprising:
means for providing a haptic impulse in response to the sensing the pressure.

18. The apparatus of claim 11, further comprising:
means for locking the bezel in place while the appliance is OFF.

19. The apparatus of claim 11, further comprising:
means for providing a haptic impulse in response to detecting the capacitive coupling substantially near the particular one of the set of electrodes.

20. The apparatus of claim 11, further comprising:
means for turning the appliance OFF if the control action is not detecting in a predetermined amount of time.
